(19) United States
(12) Patent Application Publication
(10) Pub. No.: US 2011/0120755 A1
(43) Pub. Date: May 26, 2011

(54) Flexible Display Apparatus and Method of Manufacturing Flexible Display Apparatus

(75) Inventors: Jae-Seob Lee, Young-City (KR); Dong-Un Jin, Young-City (KR); Hyung-Sik Kim, Young-City (KR)

(73) Assignee: Samsung Mobile Display Co., Ltd., Yong-City (KR)

(21) Appl. No.: 12/748,302

(22) Filed: Mar. 26, 2010

(30) Foreign Application Priority Data
Nov. 25, 2009 (KR) 10-2009-0114633

(51) Int. Cl. H05K 1/00; H01J 9/02

(52) U.S. Cl. 174/254; 445/46

(57) ABSTRACT

A flexible display apparatus and a method of manufacturing the flexible display apparatus. Even if a passivation layer is thin, the passivation layer is highly planarized, thereby preventing a protective film and the passivation layer from becoming detached from each other.

### CROSS-REFERENCE TO RELATED APPLICATIONS

This application claims the benefit of Korean Patent Application No. 10-2009-0114633, filed on Nov. 25, 2009, in the Korean Intellectual Property Office, the disclosure of which is incorporated herein in its entirety by reference.

### BACKGROUND OF THE INVENTION

1. Field of the Invention

The present embodiments relate to a flexible display apparatus and a method of manufacturing the flexible display apparatus, and more particularly, to a flexible display apparatus having a strong attachment between a protective film and a passivation layer by reducing unevenness of the passivation layer, and a method of manufacturing the flexible display apparatus.

2. Description of the Related Art

Recently, flexible display apparatuses have attracted attention as new technology in the field of displays. A flexible display apparatus is embodied on a thin substrate such as a plastic substrate, and thus is not damaged even if the flexible display apparatus is folded or rolled like paper. Currently, flexible display apparatuses have been implemented using liquid crystal displays (LCDs) including thin film transistors (TFTs) and organic light emitting diode displays (OLEDs).

A flexible display panel is manufactured by coating plastic on a support substrate, forming a barrier on the plastic, forming a backplane and then performing a thin film encapsulation (TFE) operation. A flexible display apparatus is planarized by using a thick organic pixel definition layer and forming a thick organic layer of a passivation layer during the TFE operation. Then, the flexible display panel is detached from the support substrate, and protective films are attached to top and bottom surfaces of the flexible display panel, thereby completing the manufacture of the flexible display apparatus.

In order to obtain flexibility as an intrinsic property of the flexible display apparatus, the attachment with the protective films for protecting the flexible display panel and providing durability, for example, the protective film attached to the top surface, is important. The protective film may be detached due to stress that may be generated due to poor attachment of the protective film or during repeated folding and unfolding of the flexible display apparatus. In this case, the flexible display apparatus may not function as a display apparatus after a certain point.

When permeability of the flexible display apparatus is (<10⁻⁶ g/m²/day), the passivation layer should be thin in consideration of throughput. In this case, the flexible display apparatus may not be planarized. Thus, the protective film and the passivation layer are partially attached, and thus the protective film and the passivation layer may be partially detached during repeated folding and unfolding of the flexible display apparatus.

### SUMMARY OF THE INVENTION

The present embodiments provide a flexible display apparatus having high attachment between a protective film and a passivation layer after a thin film encapsulation (TFE) operation, and a method of manufacturing the flexible display apparatus.

According to an aspect of the present embodiments, there is provided a flexible display apparatus including a substrate; a first electrode formed on the substrate; a thin inorganic pixel definition layer formed on the substrate so as to cover the first electrode and having an opening for exposing a portion of the first electrode; a second electrode formed on the thin inorganic pixel definition layer and facing the first electrode; an organic layer interposed between the first electrode and the second electrode through the opening; and a passivation layer formed on the second electrode, wherein the passivation layer is for planarizing the substrate.

According to another aspect of the present embodiments, there is provided a method of manufacturing a flexible display apparatus, including preparing a substrate; forming a first electrode on the substrate; forming a thin inorganic pixel definition layer on the substrate so as to cover the first electrode; forming an opening for exposing a portion of the first electrode by patterning the thin inorganic pixel definition layer; forming an organic layer on the first electrode through the opening; forming a second electrode facing the first electrode through the opening on the thin inorganic pixel definition layer and the organic layer; and forming a passivation layer on the second electrode in order to planarize the substrate.

The thin inorganic pixel definition layer may include at least one selected from the group consisting of silicon oxide and silicon nitride, and may have a thickness in the range of 200 to 500 nm.

The passivation layer may have any one structure of an inorganic structure, an organic structure and an organic and inorganic complex structure, and may have a thickness in the range of 500 to 1200 nm.

The flexible display apparatus may further include a driving circuit that is electrically connected to the first electrode and is driven between the first electrode and the substrate.

### BRIEF DESCRIPTION OF THE DRAWINGS

The above and other features and advantages of the present embodiments will become more apparent by describing in detail exemplary embodiments thereof with reference to the attached drawings in which:

FIGS. 1A and 1B are cross-sectional views of a flexible display apparatus according to an embodiment;

FIGS. 2 through 9 are cross-sectional views of a method of manufacturing a flexible display apparatus, according to an embodiment; and

FIGS. 10A and 10B are cross-sectional views of a passivation layer of the flexible display apparatus of FIGS. 1A and 1B.

### DETAILED DESCRIPTION OF THE INVENTION

Reference will now be made in detail to embodiments, examples of which are illustrated in the accompanying drawings. Like reference numerals in the drawings denote like elements, and thus their description will be omitted. Also, while describing the embodiments, detailed descriptions about related well-known functions or configurations that may diminish the clarity of the points of the embodiments will be omitted.

It will be further understood that the terms “comprises” and “comprising” when used in this specification do not preclude the presence or addition of one or more other elements.

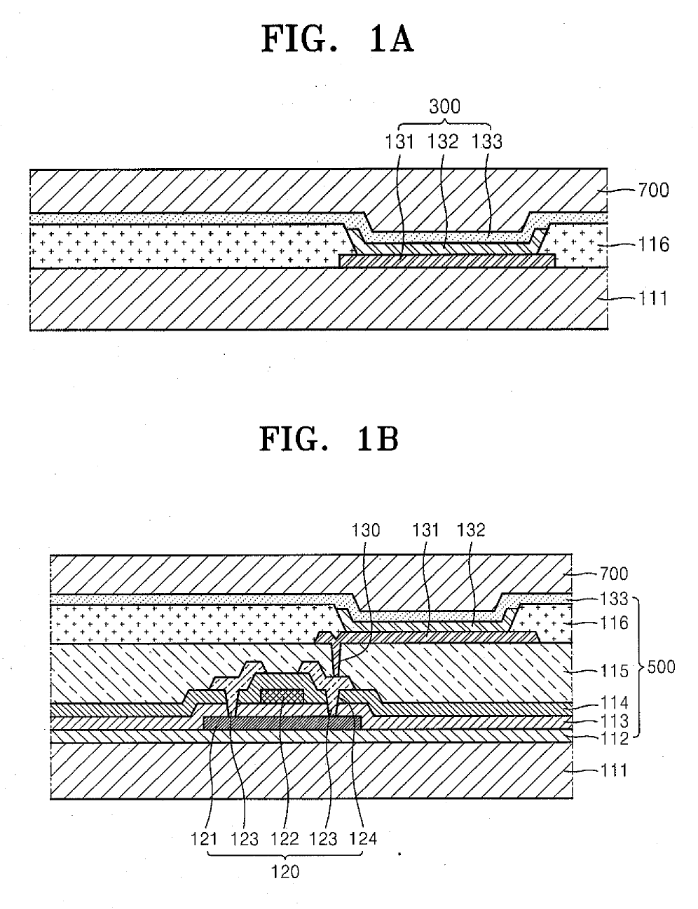

FIGS. 1A and 1B are cross-sectional views of a flexible display apparatus according to an embodiment.

Referring to FIG. 1A, the flexible display apparatus according to the present embodiment includes a substrate 111, a plurality of pixel units 300 and a passivation layer 700. The substrate 111 may be a flexible substrate comprising a metal foil such as stainless steel (SUS), or a plastic substrate which is relatively light and has a lower specific gravity than a glass substrate.

The pixel units 300 are formed on the substrate 111. The pixel unit 300 includes a first electrode 131, a second electrode 133 facing the first electrode 131, and an organic layer 132 interposed between the first electrode 131 and the second electrode 133. A pixel definition layer 116 is disposed between first electrodes 131 of the pixel units 300 and defines an emissive region. When the permeability of the flexible display apparatus is in spec (<10⁻⁶ g/m²/day), the passivation layer 700 should be thin. Thus, the thickness of the pixel definition layer 116 may be determined in consideration of a thickness of the passivation layer 700 in such a way that a protective film (not shown) and the passivation layer 700 may not be detached from each other due to unevenness of the passivation layer 700. According to the present embodiment, the pixel definition layer 116 is formed as a thin inorganic insulating layer having a thickness of from about 200 to about 500 nm, and thus the passivation layer 700 may be highly planarized even if the passivation layer 700 is thin.

In some embodiments the pixel unit 300 is covered by the passivation layer 700. The passivation layer 700 is formed by sequentially stacking an organic layer and an inorganic layer. According to the present embodiment, since the pixel definition layer 116 is a thin inorganic layer, the passivation layer 700 may be highly planarized even if the passivation layer 700 is formed to have a small thickness of from about 500 to about 1200 nm. Thus, in some embodiments, when the flexible display apparatus is manufactured, the protective film and the passivation layer 700 may not be detached from each other.

As illustrated in FIG. 1B, the flexible display apparatus may include a driving circuit 120 that is electrically connected to the pixel unit 300 and is formed on the substrate 111.

Referring to FIG. 1B, an insulating layer 112 such as a barrier layer and/or a buffer layer may be formed on the substrate 111 in order to prevent diffusion of impurities and penetration of external moisture and air, and to planarize a surface of the substrate 111.

A thin film transistor (TFT) as the driving circuit 120 is formed on the insulating layer 112. According to the present embodiment, a top gate type TFT is used. Of course, various types of TFTs may be used.

An active layer 121 of the TFT is comprising a semiconductor material and disposed on the insulating layer 112. A gate insulating layer 113 is formed to cover the active layer 121. The active layer 121 may comprise an inorganic semiconductor material such as amorphous silicon or poly silicon, or an organic semiconductor material, and may have a source region, a drain region, and a channel region disposed between the source region and the drain region.

A gate electrode 122 is disposed on the gate insulating layer 113, and an interlayer insulating layer 114 is formed to cover the gate electrode 122. Source and drain electrodes 123 are disposed on the interlayer insulating layer 114, and then a planarization layer 115 is disposed to cover the source and drain electrodes 123.

However, the above-described stack structure of the TFT is not so limited, and TFTs having various structures may be used.

The first electrode 131, which is one electrode of an organic light emitting device, is formed on the planarization layer 115, and is electrically connected to the source and drain electrodes 123 via a via hole 130.

The pixel definition layer 116 that is a thin inorganic layer is formed on the first electrode 131, and a predetermined opening is formed in the pixel definition layer 116 so as to expose the first electrode 131 through the opening.

An organic layer 132 including an emissive layer is formed on an exposed portion of the first electrode 131, and the second electrode 133 is formed to cover the organic layer 132 and the pixel definition layer 116, thereby completing the formation of a display unit 500.

The display unit 500 is covered by the passivation layer 700. The display unit 500 may be protected by the passivation layer 700 from external shocks or scratches that may be generated during manufacturing, and/or from external moisture and oxygen. The passivation layer 700 may planarize an upper portion of the substrate 111, and thus the attachment to the protective film attached to the top surface of the flexible display panel may be improved. In the case of a conventional thick organic pixel definition layer with a thickness of about 1.5 μm, the passivation layer 700 should be thick, for example having a thickness of about 2870 nm in order to planarize the passivation layer 700. When permeability of the flexible display apparatus is in spec (<10⁻⁶ g/m²/day), the passivation layer 700 should be thin, for example, having a thickness of from about 500 to about 1200 nm. Thus, in the case of a thick organic pixel definition layer, a thin passivation layer 700 may not be completely planarized. According to the present embodiment, the passivation layer 700 that is thin may be highly planarized by using the pixel definition layer 116 that is a thin inorganic layer instead of a thick organic pixel definition layer.

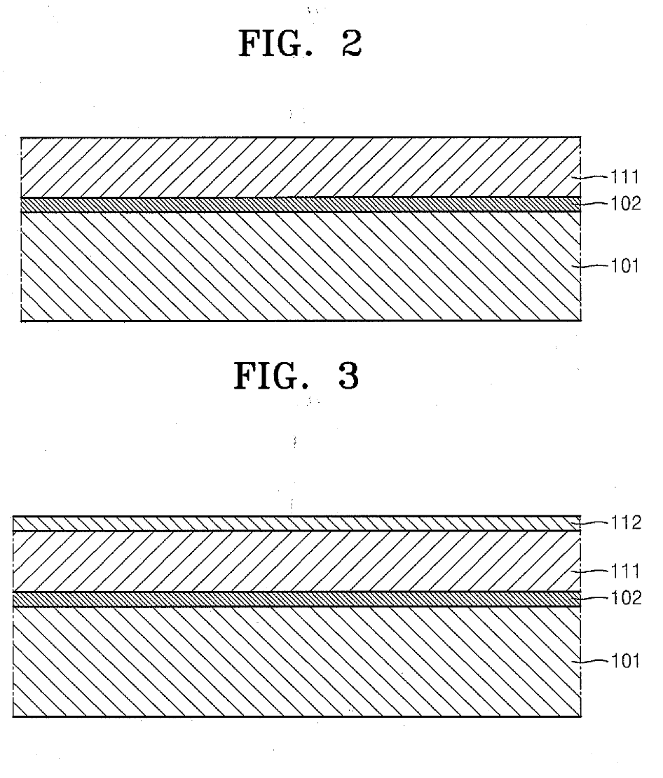

FIGS. 2 through 9 are cross-sectional views of a method of manufacturing a flexible display apparatus, according to an embodiment.

Referring to FIG. 2, a plastic substrate 111 is formed on a support substrate 101. An isolation layer 102 is formed between the support substrate 101 and the plastic substrate 111.

In a delamination process that will be described later, the support substrate 101 is detached from the plastic substrate 111 by irradiating laser beams or performing chemical dissolution on the isolation layer 102. The support substrate 101 may comprise a material that has a sufficient mechanical strength and thus is not modified although various devices or layers are formed on the support substrate 101. According to the present embodiment, the support substrate 101 is formed of glass. It will be further understood that the support substrate 101 may comprise various other materials as long as the materials have the above-described properties.

The isolation layer 102 may comprise various materials that are appropriate for the delamination process.

As the plastic substrate 111 is thinner, a display apparatus using the plastic substrate 111 is lighter and thinner. However, the thickness of the plastic substrate 111 may be ensured in such a way that the plastic substrate may support weights of layers and devices formed on the plastic substrate 111 after the support substrate 101 is detached from the plastic substrate 111. The plastic substrate 111 may have a thickness of from about 10 to about 100 μM. In the case of a thickness of about 10 μm or less, it is difficult to stably maintain shapes of layers and devices formed on the plastic substrate 111 by using the plastic substrate 111 only when the support substrate 101 is detached from the plastic substrate 111. A thickness of about 100 μm or more is not sufficient to implement a thin display device.

The plastic substrate 111 may comprise polyimide. Polyimide has excellent mechanical strength, and the maximum temperature to process polyimide is about 350° C. Thus, since heat resistance of polyimide is better than that of other polymer materials, even if a predetermined heating operation proceeds in order to form a TFT and a display device on the plastic substrate 111, the plastic substrate 111 may stably function as a flexible display substrate without drooping due to the weight of the TFT and the display devices.

Referring to FIG. 3, a buffer layer 112 comprising SiO₂ may be formed on the plastic substrate 111. The buffer layer 112 may facilitate crystallization of a semiconductor by preventing diffusion of impurities and adjusting a heat transmission speed when the semiconductor is crystallized.

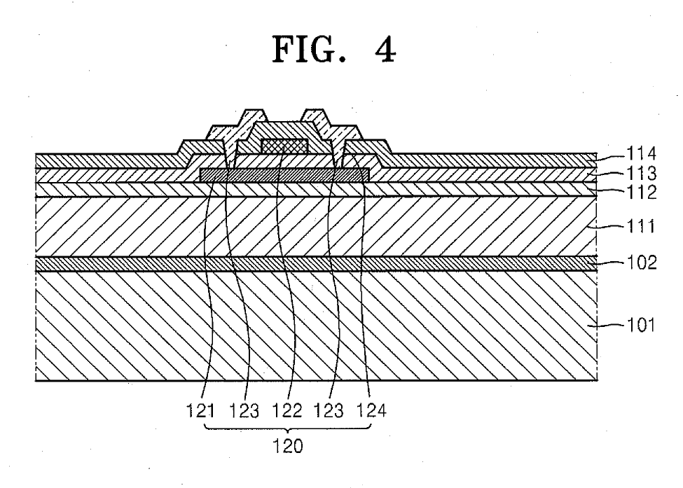

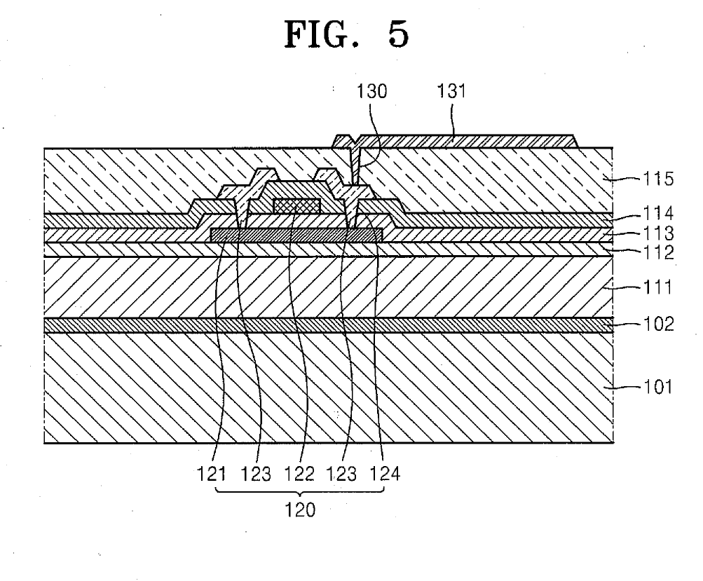

Referring to FIG. 4, a TFT 120 is formed on the buffer layer 112. In FIG. 5, the case where the TFT 120 is a top gate type TFT is illustrated. A semiconductor layer 121, a gate insulating layer 113, a gate electrode 122, the interlayer insulating layer 114, a contact hole 124, and source and drain electrodes 123 are sequentially formed on the buffer layer 112.

The semiconductor layer 121 may comprise poly silicon. In this case, a predetermined region of the semiconductor layer 121 may be doped with impurities. Of course, the semiconductor layer 121 may comprise amorphous silicon instead of poly silicon, and may comprise various organic semiconductor materials such as pentacene.

When the semiconductor layer 121 is formed of poly silicon, amorphous silicon is formed and crystallized so as to be changed to poly silicon. In order to crystallize amorphous silicon, rapid thermal annealing (RTA), solid phase crystallization (SPC), excimer laser annealing (ELA), metal induced crystallization (MIC), metal induced lateral crystallization (MILC) or sequential lateral solidification (SLS), for example, may be used. According to the present embodiment, in order to use the plastic substrate 111, a heating operation under a high temperature may be avoided. Conventionally, since a high temperature is maintained during activation of a semiconductor, the temperature of the substrate is increased up to from about 400 to about 500° C., and thus a plastic substrate may not be used. However, when a semiconductor is crystallized using a low temperature poly-silicon (LTPS) method, the semiconductor is activated by irradiating laser beams onto the semiconductor for a short period of time. Thus, a substrate is not exposed to a temperature of about 300° C. or more, and all operations are performed under a temperature of about 300° C. or less. Accordingly, the TFT 120 may comprise plastic, for example, polyimide.

The gate insulating layer 113 is formed between the semiconductor layer 121 and the gate electrode 122 in order to insulate the semiconductor layer 121 and the gate electrode 122 from each other. The gate insulating layer 113 may comprise an insulating material such as silicon oxide and silicon nitride. In addition, the gate insulating layer 113 may comprise another insulating organic material.

The gate electrode 122 may comprise various conductive materials, for example, magnesium (Mg), aluminum (Al), nickel (Ni), chromium (Cr), molybdenum (Mo), tungsten (W), molybdenum-tungsten (MoW), gold (Au) or a combination thereof. The gate electrode 122 may have various structures such as a single-layered structure and a multi-layered structure.

The interlayer insulating layer 114 may comprise an insulating material such as silicon oxide or silicon nitride. In addition, the interlayer insulating layer 114 may comprise another insulating organic material. The contact hole 124 for exposing source and drain regions may be formed by selectively removing the interlayer insulating layer 114 and the gate insulating layer 113. The source and drain electrodes 123 having a single-layered structure and a multi-layered structure may comprise the same material as that of the gate electrode 122 and disposed on the interlayer insulating layer 114 so as to fill and cover the contact hole 124.

Referring to FIG. 5, the planarization layer 115 is formed on the source and drain electrodes 123 so as to protect and planarize the TFT 120 disposed under the planarization layer 115. The planarization layer 115 may be configured to have various shapes, and may comprise an organic material such a benzocyclobutene (BCB) and acrylate, or an inorganic material such as SiNx. The planarization layer 115 may have various structures such as a double-layered structure and a multi-layered structure.

The first electrode 131 is formed on the planarization layer 115, and the first electrode 131 is electrically connected to one of the source and drain electrodes 123 via the via hole 130. The first electrode 131 may function as an anode or a cathode, and may comprise various conductive materials. In a case of a bottom emission type display apparatus in which an image is realized towards the substrate 111, the first electrode 131 may be a transparent electrode, and may comprise a material having a high work function, such as, for example, indium tin oxide (ITO), indium zinc oxide (IZO), zinc oxide (ZnO), indium (III) oxide (In₂O₃) or a combination thereof. In the case of a top emission type display apparatus in which an image is realized towards an opposite direction of the substrate 111, the first electrode 131 may be a reflective electrode, and may be formed by a reflective layer comprising, for example, silver (Ag), magnesium (Mg), aluminum (AI), platinum (Pt), lead (Pd), gold (Au), nickel (Ni) neodymium (Nd) iridium (Ir), chromium (Cr), lithium (Li), calcium (Ca) and combinations thereof and by a material having a high work function, such as ITO, IZO, ZnO, In₂O₃ or a combination thereof on the reflective layer.

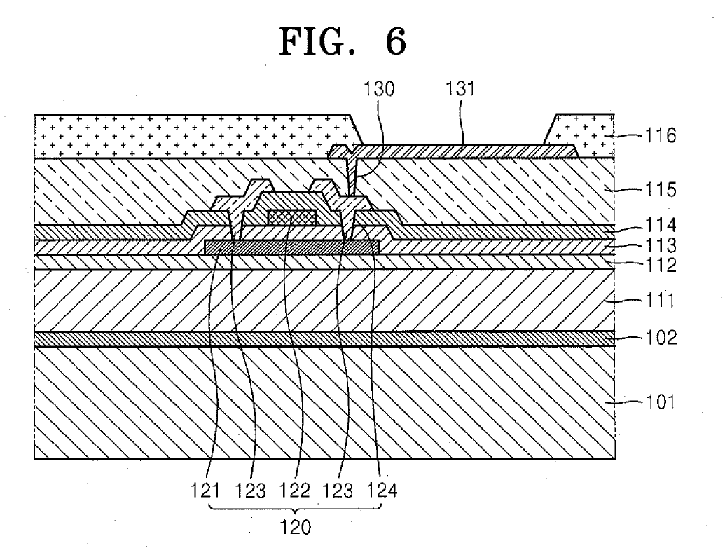

Referring to FIG. 6, an inorganic pixel definition layer 116 is formed on an entire substrate including the first electrode 131. The inorganic pixel definition layer 116 is an inorganic insulating layer for defining a unit pixel unit. The inorganic pixel definition layer 116 may comprise at least one material selected from the group consisting of a silicon oxide (SiO2) and a silicon nitride (SiNx). An opening is formed by etching the inorganic pixel definition layer 116 to expose a portion of the first electrode 131.

The thickness of the inorganic pixel definition layer 116 may be determined in such a way that a thin passivation layer may be highly planarized. When the passivation layer 700 has a small thickness of from about 500 to about 1200 nm, the inorganic pixel definition layer 116 may have a thickness of from about 200 to about 500 nm. When the thickness of the inorganic pixel definition layer 116 is from about 200 nm or less, it is difficult to prevent short between the first electrode 131 and the second electrode 133. When the thickness of the inorganic pixel definition layer 116 is about 500 nm or more, unevenness of the passivation layer 700 may be a problem. Thus, attachment with the protective film may be reduced.

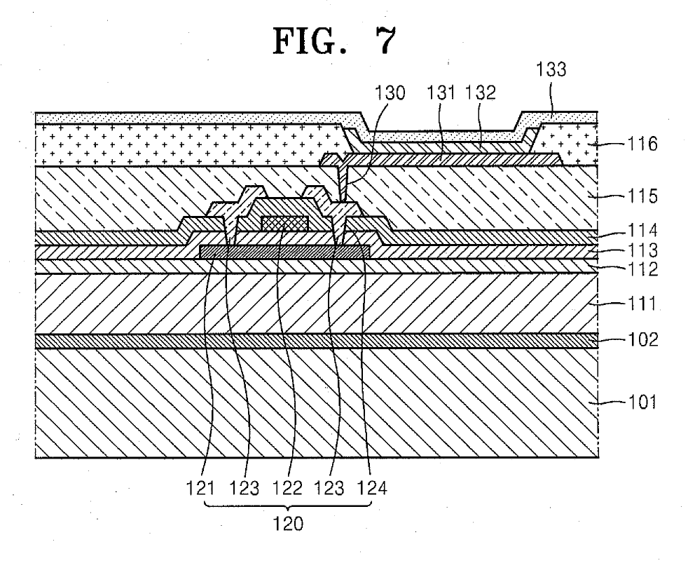

Referring to FIG. 7, the organic layer 132 is formed in the opening of the first electrode 131. The organic layer 132 includes at least an emissive layer (EML), and may further include at least one selected from the group consisting of a hole injection layer (HIL), a hole transport layer (HTL), an electron transport layer (ETL), and an electron injection layer (EIL).

The organic layer 132 may comprise a small molecular weight organic material or a polymer organic material. When the organic layer 132 is formed of a small molecular weight organic material, the organic layer 132 may be formed by stacking the HIL, the HTL, the EL, the ETL and the EIL in a single or complex structure. An organic material used for forming the organic layer 132 may include copper phthalocyanine (CuPc), N,N′-Di(naphthalene-1-yl)-N,N′-diphenyl-benzidine (NPB), tris-8-hydroxyquinoline aluminum (Alq3), or the like. In this case, the organic layer 132 may be formed using a vacuum deposition method and masks. When the organic layer 132 is formed of a polymer organic material, the organic layer 132 may include a structure including a HTL and an EML. In this case, the HTL may comprise poly-(2,4)-ethylene-dihydroxy thiophene (PEDOT). In addition, the EML may comprise a polymer organic material such as poly-phenylenevinylene (PPV), and polyfluorene. The organic layer 132 may be formed using a screen printing method and an inkjet printing method. The organic layer 132 is not limited to the above-described structure, but may have various structures.

Then, the second electrode 133 is formed on an entire substrate including the organic layer 132. The second electrode 133 may function as a cathode or an anode according to the function of the first electrode 131. In the case of a bottom emission type display apparatus in which an image is realized towards the substrate 111, the second electrode 133 may be a reflective electrode and may comprise a material having a low work function, such as Ag, Mg, Al, Pt, Pd, Au, Ni, Nd, Ir, Cr, Li, Ca or a combination thereof. In the case of a top emission type display apparatus in which an image is realized towards the second electrode 133, the second electrode 133 may be a transparent electrode, and may be formed by a metal having a low work function, such as Ag, Mg, Al, Pt, Pd, Au, Ni, Nd, Ir, Cr, Li, Ca and combinations thereof and by an auxiliary electrode layer or a bus line formed by using a conductive material such as ITO, IZO, ZnO, In₂O₃ or a combination thereof on the metal.

The first electrode 131 and the second electrode 133 are not limited to the above-listed materials. The first electrode 131 and the second electrode 133 may comprise a conductive organic material, or a conductive paste including Ag, Mg or Cu. When the conductive paste is used, the first electrode 131 and the second electrode 133 may be formed using an inkjet printing method and the conductive paste may be sintered so as to function as an electrode after printing.

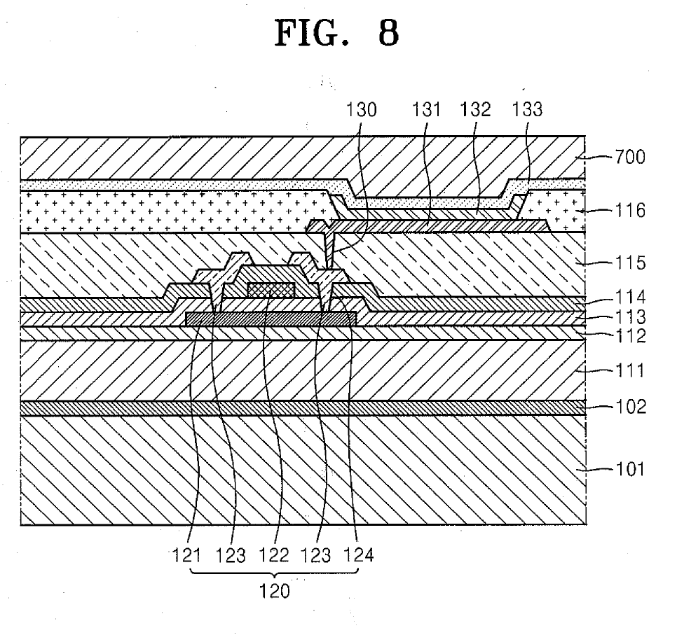

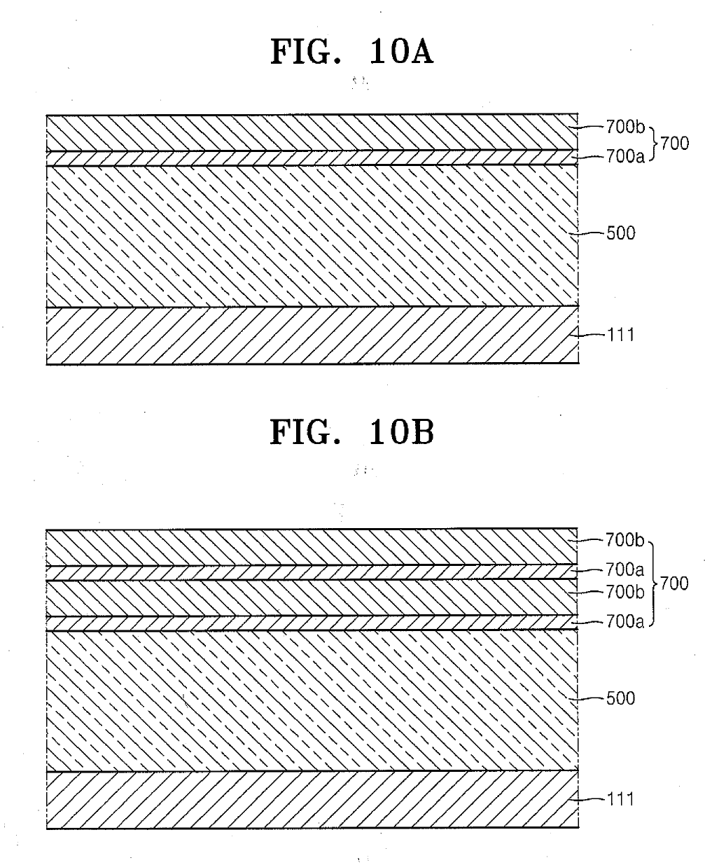

Referring to FIG. 8, the passivation layer 700 is formed on the second electrode 133. The passivation layer 700 may have an inorganic structure, an organic structure or an organic and inorganic complex structure. When the passivation layer 700 has a multi-layered structure formed by sequentially stacking an inorganic layer and an organic layer, the inorganic layer may protect the flexible display panel and may prevent the penetration of moisture, and the organic layer may planarize the flexible display panel and may fill defects of the flexible display panel. The organic layer may include an organic insulating layer comprising at least one selected from the group consisting of a general-purpose polymer (e.g., Polymethylmethacrylate (PMMA) and polystyrene (PS)), polymer derivatives having phenol groups, acryl polymers, imide polymers, arylether polymers, amide polymers, fluorine polymers, p-xylene polymers, vinyl alcohol polymers and blends thereof. The inorganic layer may include an inorganic insulating layer comprising at least one selected from the group consisting of SiO₂, SiNx, SiON, Al₂O₃, TiO₂, Ta₂O₅, HfO₂, ZrO₂, BST, PZT or combinations thereof. When the passivation layer 700 has a multi-layered structure, the passivation layer 700 may be configured as 1 dyad of an first inorganic layer 700a and second inorganic layer 700b, as shown in FIG. 10A, or the passivation layer 700 may be configured as 2 dyads of the first inorganic layer 700a and the second inorganic layer 700b, as shown in FIG. 10B. The order of stacking the first inorganic layer 700a and the second inorganic layer 700b may be reversed. The inorganic layer may comprise AlOx having a thickness of about 500 Å, and the organic layer may comprise a polymer having a thickness of about 5000 Å.

Conventionally, when a thick organic pixel definition layer is formed, a thick passivation layer of 5 dyads is required in order to planarize the flexible display panel. However, according to the present embodiment, the inorganic pixel definition layer 116 is thin, and thus the flexible display panel may be highly planarized by the passivation layer 700 of 1 dyad or 2 dyads (a thickness of from about 500 to about 1200 nm), thereby preventing a protective film attached on an upper surface of the passivation layer 700 from becoming detached.

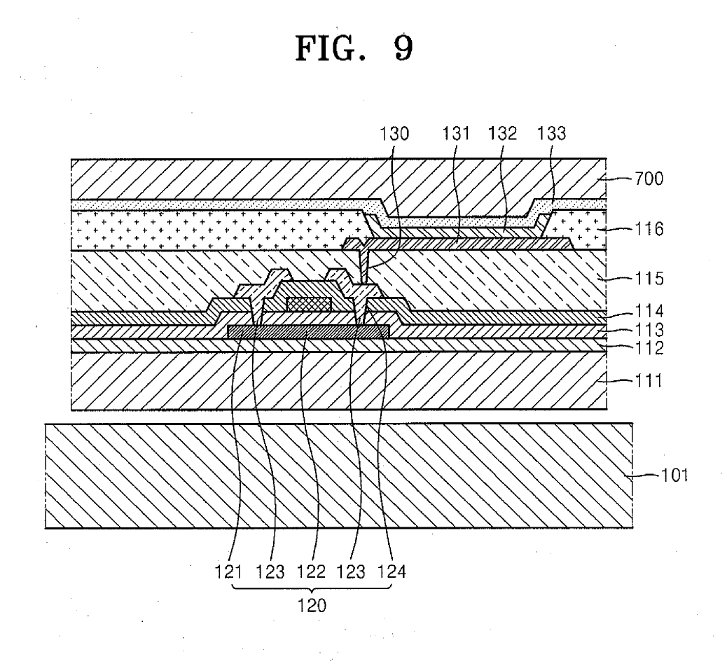

Referring to FIG. 9, the plastic substrate 111 is detached from the support substrate 101, that is, a delamination process is performed. The isolation layer 102 is delaminated by irradiating laser beams or performing chemical dissolution on the isolation layer 102, according to a material used for forming the isolation layer 102, and thus the support substrate 101 is detached from the plastic substrate 111.

Protective films are attached to top and bottom surfaces of the resulting structure prepared as described above, thereby completing manufacturing of the flexible display apparatus according to the present embodiment.

In the flexible display apparatus according to the present embodiment, the passivation layer is highly planarized by using a thin inorganic pixel definition layer even if the passivation layer is thin, thereby preventing the protective film and the passivation layer from being detached from each other.

While the present embodiments have been particularly shown and described with reference to exemplary embodiments thereof, it will be understood by those of ordinary skill in the art that various changes in form and details may be made therein without departing from the spirit and scope of the present embodiments as defined by the following claims.

What is claimed is:

1. A flexible display apparatus comprising:
a substrate;
a first electrode formed on the substrate;
a thin inorganic pixel definition layer formed on the substrate so covering the first electrode and having an opening configured to expose a portion of the first electrode;
a second electrode formed on the thin inorganic pixel definition layer and facing the first electrode;
an organic layer interposed between the first electrode and the second electrode through the opening; and
a passivation layer formed on the second electrode, wherein the passivation layer planarizes the substrate.

2. The flexible display apparatus of claim 1, wherein the thin inorganic pixel definition layer comprises at least one selected from the group consisting of silicon oxide and silicon nitride.

3. The flexible display apparatus of claim 1, wherein the thin inorganic pixel definition layer has a thickness of from about 200 to about 500 nm.

4. The flexible display apparatus of claim 1, wherein the passivation layer comprises any one of:
an inorganic structure, an organic structure and an organic and inorganic complex structure.

5. The flexible display apparatus of claim 4, wherein the passivation layer has a thickness of from about 500 to about 1200 nm.

6. The flexible display apparatus of claim 1, further comprising a driving circuit that is electrically connected to the first electrode and is driven between the first electrode and the substrate.

7. The flexible display apparatus of claim 1 wherein the substrate comprises a flexible substrate.

8. The flexible display apparatus of claim 1, wherein the substrate comprises plastic.

9. The flexible display apparatus of claim 8, wherein the substrate comprises polyimide.

10. The flexible display apparatus of claim 1, wherein the thickness of the substrate is from about 10 μm to about 100 μm.

11. A method of manufacturing a flexible display apparatus, the method comprising:
preparing a substrate;
forming a first electrode on the substrate;
forming a thin inorganic pixel definition layer on the substrate so as to cover the first electrode;
forming an opening exposing a portion of the first electrode by patterning the thin inorganic pixel definition layer;
forming an organic layer on the first electrode through the opening;
forming a second electrode facing the first electrode through the opening on the thin inorganic pixel definition layer and the organic layer, and
forming a passivation layer on the second electrode which planarizes the substrate.

12. The method of claim 11, wherein the thin inorganic pixel definition layer comprises at least one selected from the group consisting of silicon oxide and silicon nitride.

13. The method of claim of claim 11, wherein the thin inorganic pixel definition layer has a thickness of from about 200 to about 500 mu.

14. The method of claim of claim 11, wherein the passivation layer comprises any one of:
an inorganic structure, an organic structure and an organic and inorganic complex structure.

15. The method of claim 11, wherein the passivation layer has a thickness of from about 500 to about 1200 nm.

16. The method of claim of claim 11, wherein the substrate comprises a flexible substrate.

17. The method of claim of claim 11, wherein the substrate comprises plastic.

18. The method of claim of claim 18, wherein the substrate comprises polyimide.

19. The method of claim of claim 11, wherein the thickness of the substrate is from about 10 μM to about 100 μm.

20. The method of claim of claim 11, further comprising providing a driving circuit that is electrically connected to the first electrode and is driven between the first electrode and the substrate.
